(19) United States
(12) Patent Application Publication
(10) Pub. No.: US 2016/0052094 A1
(43) Pub. Date: Feb. 25, 2016

(54) SYSTEM AND METHOD FOR METALIZING VERTICALLY ALIGNED CARBON NANOTUBE ARRAY

(71) Applicant: BST NanoElectronics LLC, San Diego, CA (US)

(72) Inventors: Christopher J. Fleming, San DIego, CA (US); Sridhar Lahankar, San Diego, CA (US); Tyler Anderson, San Diego, CA (US)

(73) Assignee: BST NanoElectronics LLC

(21) Appl. No.: 14/818,867

(22) Filed: Aug. 5, 2015

Related U.S. Application Data
(60) Provisional application No. 62/040,650, filed on Aug. 22, 2014.
(60) Provisional application No. 62/040,799, filed on Aug. 22, 2014.
(60) Provisional application No. 62/045,726, filed on Sep. 4, 2014.
(60) Provisional application No. 62/045,730, filed on Sep. 4, 2014.

(51) Int. Cl. B23P 15/26; H05K 7/20

(52) U.S. Cl. CPC B23P 15/26; H05K 7/20409

(57) ABSTRACT

A method for metallizing a vertically aligned carbon nanotube array includes coupling a support structure to an actuator, the support structure supporting a vertically aligned carbon nanotube array, and vibrating the support structure with the actuator. The method can also include the step of fixedly positioning the actuator between a first member and a second member. The vibration can be consistent or it can vary in amplitude and/or frequency over time. The step of fixedly positioning can include the first member having a first mass and the second member having a second mass that is different or less than the first mass. The actuator can include a piezoelectric element. A metalizing assembly for intercalating a vertically aligned carbon nanotube array with a metal includes a first member, a support structure, a second member and an actuator. The support structure is coupled to the first member. The support structure supports the vertically aligned carbon nanotube array. The second member is coupled to the support structure. The actuator is positioned between the first member and the second member. The actuator vibrates the support structure.

### BACKGROUND

Heat sinks are a necessity in many aspects of modern-day life. FIG. 1 is a simplified illustration of a heat source 10 and a prior art heat sink 12 positioned in contact with the heat source 10. Any electrical device containing a processor, or thermal generator such as a screen, can benefit from heat sinks 12 to carry away thermal energy from the heat source 10. Heat sinks 12 inhibit these devices from overheating and/or failing, which would likely occur almost immediately in the absence of heat sinks 12, creating serious safety concerns, among other problems.

Most conventional heat sinks 12 on the market today are made at least primarily of metal, such as a zinc or copper alloy which is attached directly or via a thermal interface material (“TIM”) to the heat source 10. Heat sinks 12 can range in size from covering the interfacial area of the heat source 10 to several times the size of the heat source 10. Most prior art heat sinks 12 contain fins 14, such as those illustrated in FIG. 1, that enhance the spread and dissipation of heat over a larger surface area. For example, a heat source 10 that measures 5 cm×5 cm covers an area of 25 cm². By comparison, the prior art heat sink 12 illustrated in FIG. 1 would have an effective surface area of approximately 260.3 cm², which is roughly ten times that of the heat source 10.

Heat sinks 12, as well as heat spreaders, heat tubes and thermal interface materials all work, sometimes in concert to transfer heat away from the heat source 10. The heat sink 12 is usually the last in this chain and owes its effectiveness to the high surface area boundary with the surrounding gas, in most cases, air. The thermal energy from the heat sink 12 is transferred to the gas molecules via surface collisions. The energy is then dissipated through gas-gas energy transfer. Classical heat sinks 12 have substantially reached the limit of machinability in terms of the maximization of surface area.

Recently, vertically aligned carbon nanotube (VACNT) arrays with various polymers added to the arrays have been used as heat sinks 12. In one conventional metalizationvertically aligned process used to produce metalized poly-vertically aligned carbon nanotube thermal interface materials (MPoly-VACNT TIM), thermal evaporation is used to deposit metal onto the tips of the VACNT. However, these conventional methods of metal evaporation are not altogether satisfactory. For example, these prior art methods do not sufficiently allow for intercalation of the metal into the VACNT array. It logically follows that with these typical methods, the metal does not adequately or completely flow or penetrate to the level of a support substrate upon which the VACNT sits.

### SUMMARY

The present invention is directed toward a method for metallizing a vertically aligned carbon nanotube array. In one embodiment, the method includes the steps of coupling a support structure to an actuator, the support structure supporting a vertically aligned carbon nanotube array, and vibrating the support structure with the actuator.

In one embodiment, the method further includes the step of depositing a metal onto the vertically aligned carbon nanotube array while vibrating the support structure with the actuator.

In some embodiments, the metal can be selected from the group consisting of a metalloid, a transition metal, a metal alloy and a combination of a transition metal and a non-transition metal.

In certain embodiments, the step of depositing can include using chemical vapor deposition. Alternatively, the step of depositing can include using physical vapor deposition.

In one embodiment, the step of depositing includes the step of using low-pressure thermal evaporation.

In some embodiments, the step of vibrating the support structure includes vibrating the support structure with the actuator at a rate of between approximately 1 Hz and approximately 10,000 Hz.

In certain embodiments, the step of vibrating the support structure includes vibrating the support structure with the actuator at a rate that changes over time.

In various embodiments, the method further includes the step of fixedly positioning the actuator between a first member and a second member.

In some embodiments, the step of fixedly positioning includes the actuator directly contacting the first member and the second member.

In certain embodiments, the step of fixedly positioning includes the first member having a first mass and the second member having a second mass that is less than the first mass.

In various embodiments, the step of fixedly positioning includes positioning the second member substantially between the first member and the support structure.

In some embodiments, the step of coupling includes holding the support substrate in position between two substrate holders.

In many embodiments, the actuator includes one or more piezoelectric elements.

The present invention is also directed toward a metalizing assembly for intercalating a vertically aligned carbon nanotube array with a metal. In certain embodiments, the metalizing assembly includes a first member, a support structure, a second member and an actuator. The support structure can be coupled to the first member. The support structure can be configured to support the vertically aligned carbon nanotube array. The second member can be coupled to the support structure. The actuator can be fixedly positioned between the first member and the second member. Further, the actuator can be configured to selectively vibrate the support structure.

In some embodiments, the actuator can be configured to vibrate the support structure at a rate of between approximately 1 Hz and approximately 10,000 Hz, or approximately 2 Hz and approximately 1500 Hz.

In certain embodiments, the actuator can be configured to vibrate the support structure at a rate that changes over time.

In various embodiments, the second member can be positioned between the first member and the support structure.

In some embodiments, the first member has a first mass, and the second member has a second mass that is less than the first mass.

In certain embodiments, one of the first member and the second member can have a tri-arm configuration.

In one embodiment, each of the first member and the second member have a tri-arm configuration.

In many embodiments, the actuator can include a piezoelectric element.

The present invention is also directed toward a metalized vertically aligned carbon nanotube array and/or a heat sink that is manufactured using any of the devices and/or methods provided herein.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified side view of a heat source and a prior art heat sink;

FIG. 2 is a top view taken with the use of a scanning electron microscope (SEM) of a portion of a metalized vertically aligned carbon nanotube array, and a simplified representative illustration of one carbon nanotube;

FIG. 3 is a perspective view of one embodiment of a support substrate and a metalizer assembly having features of the present invention;

FIG. 4 is a cross-sectional view of the metalizer assembly and the support substrate taken on line 4-4 in FIG. 3, with a vertically aligned carbon nanotube array secured to the support substrate;

FIG. 5 is a simplified side view of the support substrate and a portion of one embodiment of a metalized vertically aligned carbon nanotube array following processing by the metalizer assembly;

FIG. 6 is a simplified side view of the support substrate and a portion of another embodiment of the metalized vertically aligned carbon nanotube array following processing by the metalizer assembly; and

FIG. 7 is a simplified side view of the support substrate and a portion of another embodiment of the metalized vertically aligned carbon nanotube array following processing by the metalizer assembly.

### DESCRIPTION

A metalized vertically aligned carbon nanotube (“MVACNT”) heat sink described and illustrated herein addresses this and other challenges through guided molecular assembly of vertically aligned carbon nanotube (“VACNT”) arrays and subsequent deposition of metal on the nanotubes and substrate. Carbon nanotubes (“CNT”) themselves have an extremely high thermal conductivity, on the order of roughly 1000 W/(m*K), along and through the carbon Tr-orbitals which compose the curved planes of their long axes. The deposition of metal increases the effectiveness of the structure of this sink by allowing both phonon and electronic thermal conduction through the nanotubes. One of the key advantages to the MVACNT heat sink design is the air-exposed surface area.

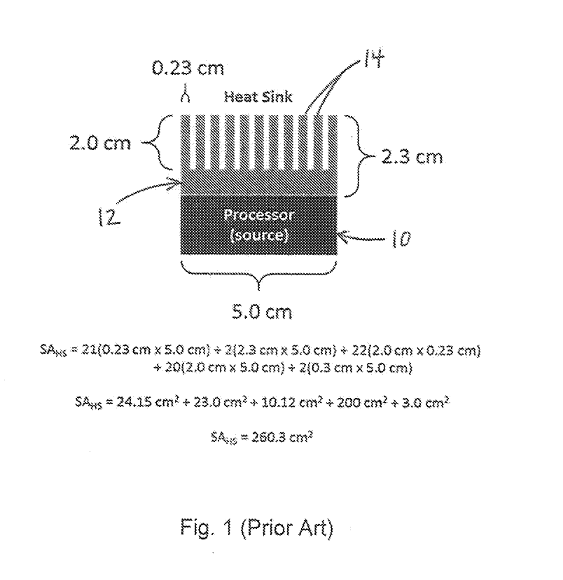

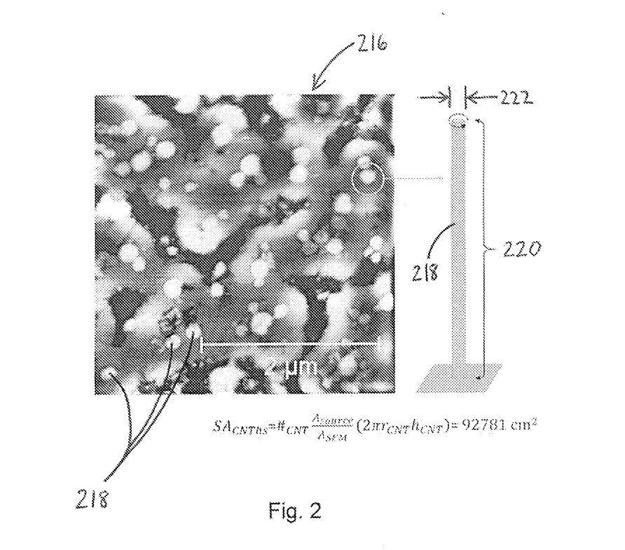

FIG. 2 is a top view of a portion of an MVACNT array 216 taken with a scanning electron microscope (SEM). The SEM image in FIG. 2 has an area of approximately 11 μm², and shows one embodiment of the MVACNT array 216 which has been embedded with TiO2 for ease of counting the tips of single nanotubes 218 within the array 216. Within the image, there are approximately 65 discernable carbon nanotubes 218. The average diameter of each of the nanotubes 218 is approximately 100 nm with an approximate 0.2 cm height. In this embodiment, the density of carbon nanotubes 218 in this array 216 is at least approximately 590 million carbon nanotubes 218 per cm². Using the formula derived from the image and carbon nanotubes 218 schematic, a surface area of an average nanotube 218 can be calculated and scaled to the source surface area used previously, e.g. 25 cm². Thus, in this example, the total surface area of the carbon nanotube array 216 in this embodiment equals 92,781 cm², which is greater than approximately 3,700 cm² for each cm² of the source surface area. This surface area of the carbon nanotube array 216 is roughly 357 times greater than the surface area of the conventional heat sink 12 (illustrated in FIG. 1). Even at 10% efficiency compared to the heat sink 12 in FIG. 1, the MVACNT heat sink 216 would perform at least approximately 35 times more effectively.

In non-exclusive, alternative embodiments, a density of carbon nanotubes 218 in a carbon nanotube array 216 can be within the range of 1.0×10⁴ to 1.0×10⁹ carbon nanotubes 218 (or greater) per cm². Further, each of a plurality of the carbon nanotubes 218 can have a nanotube height 220 of between 0.001 cm and 1.0 cm. Additionally or alternatively, each of a plurality of the carbon nanotubes 218 can have a nanotube diameter 222 of between 10 nm and 10 μm. In still other embodiments, the nanotube height 220 of each of the plurality of the carbon nanotubes 218 can be less than 0.001 cm or greater than 1.0 cm. and/or the nanotube diameter 222 of each of the plurality of the carbon nanotubes 218 can be less than 10 nm or greater than 10 μm. Still alternatively, or in addition, by varying the density, the nanotube height 220 and/or the nanotube diameter 222 of the carbon nanotubes 218, a total surface area of the carbon nanotube array 216 is achieved which is within the range of 10 cm² to 10,000 cm² for each cm² of source surface area.

It is understood that the specific densities, spacing, heights, diameters, etc. of the carbon nanotubes 218 and their arrays 216 can be varied by certain methods that include varying the manufacturing processes and materials. For example, the use of different substrates, metal catalysts, reactionary and/or passive gasses in conjunction with varying time, temperature and pressure during certain steps of the growing process can widely impact the density of the carbon nanotube array 216, the spacing between the carbon nanotubes 218, and/or the nanotube height 220 and/or nanotube diameter 222 of the carbon nanotubes 218 within the carbon nanotube array 216.

The MVACNT heat sink 216 was designed to meet the continuing thermal challenges stemming from the ever-increasing density of devices per processor and decrease in heat source size. In addition, the low profile of the MVACNT heat sink 216 will allow for insertion into volumes where only very thin heat spreaders can currently reside.

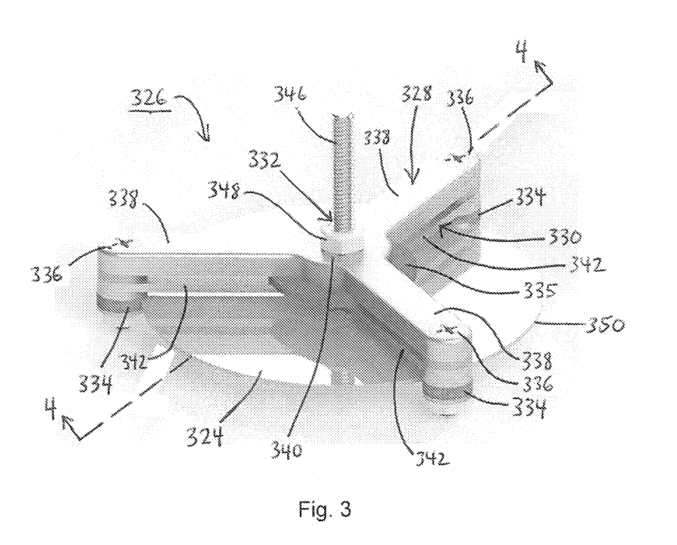

In one embodiment, the manufacture of the MVACNT heat sink 216 can generally include a two-step process. In the first step, chemical vapor deposition (“CVD”), or any other suitable method, is employed to grow VACNT from a nanotemplated transition metal catalyst on a support substrate 324 (illustrated in FIG. 3). At least some of the controls of the CVD process are: gas type (typically methane, ethylene, etc.), temperature (approximately 500-850° C.), pressure (between approximately less than 1 and 50 atm) and/or flow rate.

Second, the process of metalization occurs. To address the mechanical challenges stated herein, as well as other difficulties, the manufacturing method provided herein for the MVACNT heat sink 216 was developed. Referring now to FIG. 3, as an overview, the manufacturing method for the MVACNT heat sink 216 (illustrated in FIG. 2) can apply mid- to high-frequency modulation via one or more actuators, such as a piezoelectric actuator, or other suitable types of actuators or motors (hereinafter referred to generally as “actuator”) to a VACNT array grown on a solid support substrate.

FIG. 3 is a perspective view of one embodiment of a support substrate 324 and a metalizer assembly 326. The support substrate 324 can be formed from any suitable material that can support VACNT. For example, in one embodiment, the support substrate 324 is formed substantially from silicon or a silicon-based material.

In the embodiment illustrated in FIG. 3, the metalizer assembly 326 includes a radial arm design. In one embodiment, the metalizer assembly 326 includes one or more of an upper member 328 (also referred to herein as a “first member”), a spaced apart lower member 330 (also referred to herein as a “second member”), a member fastener 332, one or more substrate holders 334, one or more actuators 335 (only one actuator 335 is illustrated in FIG. 3), and one or more substrate fasteners 336, It is recognized that the terms “upper member” and “lower member” are used for orientation purposes only relative to the metalizer assemblies illustrated in the Figures, and are not intended to be limiting in any manner with respect to other possible orientations of the metalizer assembly. Further, in some embodiments, at least one of the first member 328 and the second member 330 are omitted from the metalizer assembly 326.

In the embodiment illustrated in FIG. 3, the first member 328 includes a plurality of first arms 338 (three first arms 338 are illustrated in FIG. 3) and a first hub 340. In one embodiment, the first arms 338 are oriented in radially in a spoke-like manner relative to the first hub 340. It is recognized that the first member 328 can have any number of first arms 338, greater or fewer than three. In an alternative embodiment, the first member 328 can have a different configuration than a spoke-type configuration illustrated in the Figures. In various alternative non-exclusive embodiments, the first member 328 can be somewhat disk-shaped, triangular, square, linear, or the first member 328 can have any other suitable geometry. The first member 328 can be formed from any relatively rigid material, such as various metals or metal alloys, ceramics, or other suitable materials.

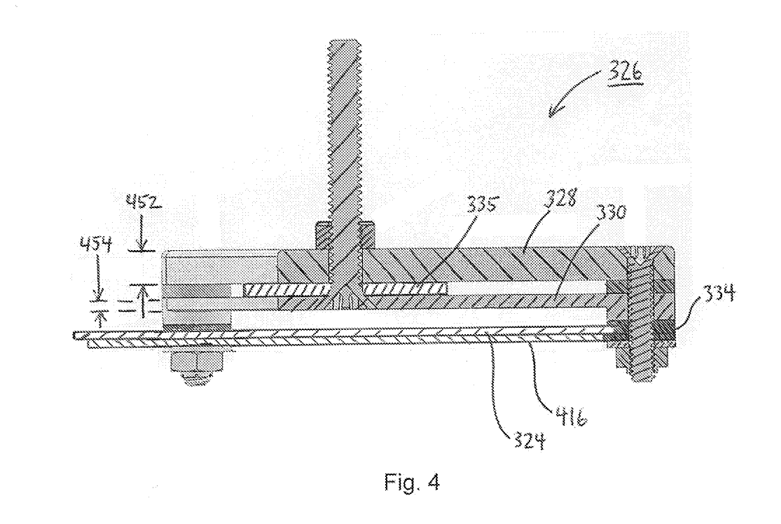

In the embodiment illustrated in FIG. 3, the second member 330 is spaced apart from the first member 328. In this embodiment, the second member 330 includes a plurality of second arms 342 (three second arms 342 are illustrated in FIG. 3) and a second hub 344 (illustrated in FIG. 4, for example). In one embodiment, the second arms 342 are oriented in radially in a spoke-like manner relative to the second hub 344. It is recognized that the second member 330 can have any number of second arms 342, greater or fewer than three. In an alternative embodiment, the second member 330 can have a different configuration than a spoke-type configuration illustrated in the Figures. In various alternative non-exclusive embodiments, the second member 330 can be somewhat disk-shaped, triangular, square, linear, or the second member 330 can have any other suitable geometry. In one embodiment, the second member 330 can have a substantially similar configuration (as viewed from above in FIG. 3) as the first member 328. Still alternatively, the second member 330 can have a different configuration (as viewed from above in FIG. 3) than the first member 328. The second member 330 can be formed from any relatively rigid material, such as various metals or metal alloys, ceramics, or other suitable materials. In one embodiment, the second member 330 is positioned between the first member 328 and the support substrate 324.

In the embodiment illustrated in FIG. 3, the member fastener 332 couples and/or connects the first member 328 to the second member 330. In one embodiment, the member fastener 332 can include a threaded member 346 such as a screw or a bolt, and a threaded tightener 348 such as a nut. Alternatively, other suitable types of fasteners can be used for the member fastener 332.

The substrate holders 334 hold the support substrate 324 in position. In the embodiment illustrated in FIG. 3, the substrate holders 334 can abut a perimeter edge 350 of the support substrate 324 with enough force to hold the support substrate in place. Alternatively, the substrate holders 334 can contact or abut the support substrate 324 at a different location than the perimeter edge 350.

In one embodiment, the substrate holders 334 can be formed from a somewhat resilient material having a relatively high Young's modulus. In certain embodiments, the number of substrate holders 334 corresponds to the number of first arms 338 and/or second arms 342. For example, in the embodiment illustrated in FIG. 3, the metalizer assembly 326 includes three substrate holders 334. Alternatively, the metalizer assembly 326 can include a quantity of substrate holders 334 that is greater or fewer than the number of first arms 338 and/or second arms 342.

In various embodiments, the actuator 335 causes direct movement, e.g. vibration of the first member 328 and the second member 330. The actuator 335 also causes indirect vibration of the substrate holders 334, and thus, the support substrate 324, due to the movement and/or vibration of the first member 328 and the second member 330. In the embodiment illustrated in FIG. 3, the actuator 335 is fixedly positioned directly between the first member 328 and the second member 330 so that the actuator 335 is in direct contact with the first member 328 and the second member 330. Alternatively, the actuator 335 may not be in direct contact with the first member 328 and/or the second member 330. In one embodiment, the actuator 335 is positioned directly between the first hub 340 and the second hub 344 (illustrated in FIG. 4). Alternatively, the actuator 335 can be positioned in other suitable locations to cause the desired movement and/or vibration of the support substrate 324 (directly or indirectly).

In one embodiment, the actuator 335 can include one or more piezoelectric elements. Alternatively, the actuator 335 can include other suitable types of actuation devices that cause the desired movement and/or vibration of the support substrate 324 (directly or indirectly). The size and/or shape of the actuator 335 can vary to suit the design requirements of the metalizer assembly 326. In one embodiment, the actuator 335 can be disk-shaped or circular. Alternatively, the actuator 335 can have another suitable configuration or geometry.

The substrate fasteners 336 maintain the positioning of the support substrate 324 relative to the first member 328, the second member 330, the substrate holders 334 and the actuator 335 so that the movement of the actuator 335 is satisfactorily transferred to the support substrate 324. In one embodiment, the actuator 335 can vibrate at a frequency between approximately 1 Hz to approximately 10,000 Hz. In non-exclusive alternative embodiments, the frequency of vibration can be approximately 2 Hz to approximately 1,000 Hz, approximately 5 Hz to approximately 500 Hz, or approximately 10 Hz to approximately 100 Hz. Alternatively, the actuator 335 can vibrate at frequencies outside of the foregoing ranges. Still alternatively, the actuator 335 can vibrate at rates that fluctuate. In one non-exclusive embodiment, the actuator 335 can vibrate for a certain time period at one vibration rate, and then change the vibration rate for another period of time. This fluctuation can continue with any number of vibration frequencies for any periods of time. Still alternatively, the vibration rate can gradually change over time. In another embodiment, the amplitude of the vibration can be constant, or the amplitude of the vibration can change over time.

FIG. 4 is a cross-sectional view of the metalizer assembly 326 and the support substrate 324 taken on line 4-4 in FIG. 3, with a vertically aligned carbon nanotube array 416 secured to the support substrate 324. During the metalization step, chemical vapor deposition and/or physical vapor deposition can be used with the metalizer assembly 326 in order to metalize the VACNT array 416. The types of metals that can be used to metalize the VACNT array 416 can include any metaloids, transition metals, metal alloys, and/or a combination of transition metals and non-transition metals (collectively referred to herein simply as “metal(s)”).

In the embodiment illustrated in FIG. 4, the first member 328 has a first thickness 452 that is greater than a second thickness 454 of the second member 330. In one embodiment where the first member 328 and the second member 330 are formed from substantially the same material, the first member 328 would have a greater mass than the second member 330. In this embodiment, or any embodiment where the first member 328 has a mass that is greater than the second member 330, a higher level of top stabilization occurs. With this design, in-plane support substrate 324 bending is inhibited, while vibrational transfer to the supported VACNT array 216 is increased. Therefore, the bulk of the vibration of the actuator 335 transfers through the second member 330 through the substrate holders 334 to the support substrate 324, and ultimately to the VACNT array 416. In alternative embodiments, the first member 328 has a mass that is substantially the same or is less than the mass of the second member 330.

In some embodiments, the relatively high frequency of the vibration transfers to the VACNT array 416, creating local break points in the cross-plane Van der Waals forces between the individual carbon nanotubes 218 (illustrated in FIG. 2). In one embodiment, the vibrational motion of the actuator 335 as transferred to the carbon nanotubes 218 can be on a variable time scale, while the impinging transition metal from the chemical and/or physical vapor deposition process can be at a relatively steady state. With this design, the intercalation of the metal(s) can be controlled, even with carbon nanotubes 218 having different nanotube lengths 220 (illustrated in FIG. 2) and nanotube diameters 222 (illustrated in FIG. 2). Alternatively, the time scale of the vibrational motion of the actuator 335, and/or the rate of impinging metal(s) from the chemical and/or physical vapor deposition process can be tailored to suit the design requirements of the MVACNT heat sink manufacturing process.

FIG. 5 is a simplified side view of a portion of a MVACNT heat sink 500 and a portion of the support substrate 324 and a portion of one embodiment of a metalized vertically aligned carbon nanotube (MVACNT) array 556 following processing by the metalizer assembly 326 (illustrated in FIG. 3). In this embodiment, the MVACNT array 556 includes a plurality of carbon nanotubes 518 (seven carbon nanotubes 518 are illustrated in FIG. 5) which are substantially completely intercalated with the metal(s) 558 described herein.

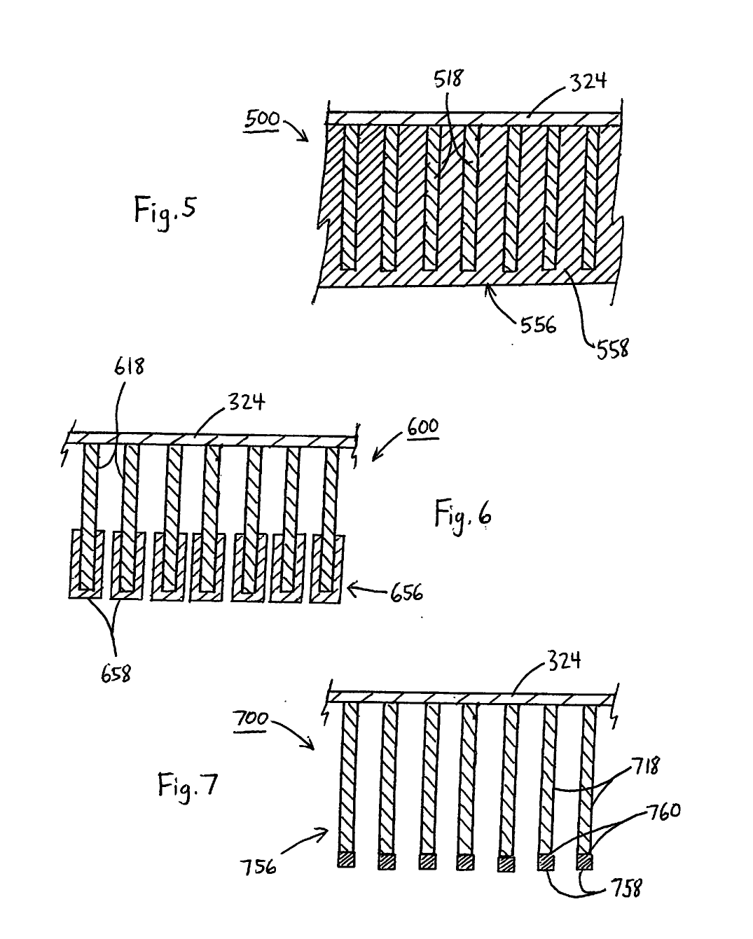

FIG. 6 is a simplified side view of a portion of a MVACNT heat sink 600 and a portion of a portion of the support substrate 324 and a portion of another embodiment of a metalized vertically aligned carbon nanotube (MVACNT) array 656 following processing by the metalizer assembly 326 (illustrated in FIG. 3). In this embodiment, the MVACNT array 656 includes a plurality of carbon nanotubes 618 (seven carbon nanotubes 618 are illustrated in FIG. 6) which are partially intercalated with the metal(s) 658 described herein.

FIG. 7 is a simplified side view of a portion of a MVACNT heat sink 700 and a portion of a portion of the support substrate 324 and a portion of another embodiment of a metalized vertically aligned carbon nanotube (MVACNT) array 756 following processing by the metalizer assembly 326 (illustrated in FIG. 3). In this embodiment, the MVACNT array 756 includes a plurality of carbon nanotubes 718 (seven carbon nanotubes 718 are illustrated in FIG. 7) having distal ends 760 onto which the metal(s) 758 have only been deposited.

Although FIGS. 5-7 illustrate three possible outcomes while utilizing the metalizer assembly 326 described herein, it is understood that the VACNT arrays 556, 656, 756, can be metalized to any desired extent with the described metalizer assembly 326 by adjusting the vibration rate, time of vibration at different rates, spacing between carbon nanotubes, type of metal(s) used in the metalization step, etc. Additionally, the effectiveness of the eventual MVACNT heat sink 500, 600, 700, that is manufactured by the methods described herein can likewise be tailored based on those and other factors known to those skilled in the art.

The method of manufacture of the MVACNT heat sink 500, 600, 700, meets the continuing thermal challenges stemming from the ever-increasing density of devices per processor and decrease in source size. In addition, the methods of manufacture provided herein create a low profile of the MVACNT heat sink 500, 600, 700, and will allow for insertion into volumes where only very thin heat spreaders can currently reside.

Embodiments of the present invention are described herein in the context of a method of manufacture of the MVACNT heat sink 500, 600, 700. Those of ordinary skill in the art will realize that the following detailed description of the present invention is illustrative only and is not intended to be in any way limiting. Other embodiments of the present invention will readily suggest themselves to such skilled persons having the benefit of this disclosure.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

It is understood that although a number of different embodiments of methods of manufacture of the MVACNT heat sink 500, 600, 700, have been described herein, one or more features of any one embodiment can be combined with one or more features of one or more of the other embodiment, provided that such combination satisfies the intent of the present invention.

While a number of exemplary aspects and embodiments of the method of manufacture of the MVACNT heat sink 500, 600, 700, have been shown and disclosed herein above, those of skill in the art will recognize certain modifications, permutations, additions and sub-combinations thereof. It is therefore intended that the system and method shall be interpreted to include all such modifications, permutations, additions and sub-combinations as are within their true spirit and scope, and no limitations are intended to the details of construction or design herein shown.

What is claimed is:

1. A method for metalizing a vertically aligned carbon nanotube array, the method comprising the steps of:
coupling a support structure to an actuator, the support structure supporting a vertically aligned carbon nanotube array; and
vibrating the support structure with the actuator.

2. The method of claim 1 further comprising the step of depositing a metal onto the vertically aligned carbon nanotube array while vibrating the support structure with the actuator.

3. The method of claim 2 wherein the metal is selected from the group consisting of a metaloid, a transition metal, a metal alloy and a combination of a transition metal and a non-transition metal.

4. The method of claim 2 wherein the step of depositing includes using chemical vapor deposition.

5. The method of claim 2 wherein the step of depositing includes using physical vapor deposition.

6. The method of claim 2 wherein the step of depositing includes the step of using low-pressure thermal evaporation.

7. The method of claim 2 wherein the step of vibrating the support structure includes vibrating the support structure with the actuator at a rate of between approximately 1 Hz and approximately 10,000 Hz.

8. The method of claim 2 wherein the step of vibrating the support structure includes vibrating the support structure with the actuator at a rate that changes over time.

9. The method of claim 1 further comprising the step of fixedly positioning the actuator between a first member and a second member.

10. The method of claim 9 wherein the step of fixedly positioning includes the actuator directly contacting the first member and the second member.

11. The method of claim 9 wherein the step of fixedly positioning includes the first member having a first mass and the second member having a second mass that is less than the first mass.

12. The method of claim 9 wherein the step of fixedly positioning includes positioning the second member substantially between the first member and the support structure.

13. The method of claim 1 wherein the step of coupling includes holding the support substrate in position between two substrate holders.

14. The method of claim 1 wherein the actuator includes a piezoelectric element.

15. A metalized vertically aligned carbon nanotube array that is manufactured using the method of claim 1.

16. A metalizing assembly for intercalating a vertically aligned carbon nanotube array with a metal, the metalizing assembly comprising:
a first member;
a support structure that is coupled to the first member, the support structure being configured to support the vertically aligned carbon nanotube array;
a second member that is coupled to the support structure; and
an actuator that is fixedly positioned between the first member and the second member, the actuator being configured to selectively vibrate the support structure.

17. The metalizing assembly of claim 16 wherein the actuator is configured to vibrate the support structure at a rate of between approximately 2 Hz and approximately 1500 Hz.

18. The metalizing assembly of claim 16 wherein the actuator is configured to vibrate the support structure at a rate that changes over time.

19. The metalizing assembly of claim 16 wherein the second member is positioned between the first member and the support structure.

20. The metalizing assembly of claim 19 wherein the first member has a first mass, and the second member has a second mass that is different than the first mass.

21. The metalizing assembly of claim 19 wherein the first member has a first mass, and the second member has a second mass that is less than the first mass.

22. The metalizing assembly of claim 16 wherein one of the first member and the second member have a tri-arm configuration.

23. The metalizing assembly of claim 16 wherein each of the first member and the second member have a tri-arm configuration.

24. The metalizing assembly of claim 16 wherein the actuator includes a piezoelectric element.

25. A metalized vertically aligned carbon nanotube array that is manufactured using the apparatus of claim 16.
